(19) United States
(12) Patent Application Publication
(10) Pub. No.: US 2024/0250557 A1
(43) Pub. Date: Jul. 25, 2024

(54) AN ELECTRIC LOAD NETWORK AND METHOD FOR ADJUSTING AN OPERATION FREQUENCY OF AN ELECTRICITY GRID IN REAL TIME

(71) Applicant: FIRMUS TECHNOLOGIES PTY LTD, Cremorne, VIC (AU)

(72) Inventor: Jonathan LEVEE, St Leonards, Tasmania (AU)

(21) Appl. No.: 18/558,012

(22) PCT Filed: Sep. 15, 2021
(86) PCT No.: PCT/AU2021/051062

§ 371 Date: Oct. 30, 2023

(30) Foreign Application Priority Data
Apr. 30, 2021 (AU) 2021901293

(51) Int. Cl. H02J 13/00; H02J 3/02; H02J 3/12

(52) U.S. Cl. CPC H02J 13/00014; H02J 3/02; H02J 3/12; H02J 13/00002; H02J 13/00026

(57) ABSTRACT

There is provided an electric load network (200) for adjusting an operation frequency of an electricity grid (101) in real time. The electric load network (200) may comprise: a set of computing devices (201); a site server (203) that is connected to the set of computing devices (201); a frequency reader (205) that is connected to the site server (203), the frequency reader (205); wherein the site server (203) is configured to obtain from the frequency reader (205) the operation frequency of the electricity grid (101); determine a frequency difference between the operation frequency and a reference operation frequency; and instruct the set of computing devices (201) to change the collective operation power of the set of computing devices (201) based on the frequency difference to adjust the operation frequency of the electricity grid (101).

### FIELD OF THE INVENTION

The present disclosure relates to an electricity grid, particularly, relates to adjusting an operation frequency of the electricity grid in real time.

### BACKGROUND OF THE INVENTION

An electricity system operates at an operation frequency. The operation frequency needs to be within a safe frequency range or frequency band defined by a primary operation frequency and a frequency deviation for the electricity system to operate safely. For example, the primary operation frequency of the electricity system is 50 Hz in Australia, and the frequency deviation is 0.15 Hz. That means if the electricity system operates within the frequency band between 49.85 Hz and 50.15 Hz, it is safe for the supply side to generate electricity energy and for the load side to consume the electricity energy. The supply side refers to power plants that generate the electricity energy, while the load side refers to the devices that consume the electricity energy generated by the supply side. There is also an electricity transmission and distribution network between the supply side and the load side, referred to as the electricity grid or “grid”, which is designed to transmit and distribute the electricity energy generated by the supply side to the load side.

The operation frequency may fluctuate with the power of the supply side and/or the power of the load side. For example, the operation frequency of the electricity grid may drop due to a fault of an electric generator (i.e., loss of electricity supply) or may ramp up due to the start of an electric generator (i.e., increase of electricity supply). The operation frequency of the electricity grid may also drop due to connection of loads to the electricity grid (e.g., increase of load during peak hours) or may ramp up if the loads are disconnected from the electricity grid. If the fluctuation of the operation frequency goes beyond the safe frequency band, which is between 49.85 Hz and 50.15 Hz in Australia as set out above, it may cause damages to the supply side (for example, the generators in the power plants) or the load side (for example, electric equipment that consumes electricity).

Therefore, there is a need for a system and method for adjusting the operation frequency of the electricity grid in response to the frequency fluctuation, particularly, outside the safe frequency band, in real time to make sure the electricity system operates safely.

Any discussion of the background art throughout the specification should in no way be considered as an admission that such background art is prior art, nor that such background art is widely known or forms part of the common general knowledge in the field in Australia or any other country.

### SUMMARY OF THE INVENTION

There is provided an electric load network for adjusting an operation frequency of an electricity grid in real time. The electric load network may comprise:
a set of computing devices interconnected to perform one or more computing tasks, the set of computing devices being configured to electrically connect to the electricity grid to be powered by the electricity grid in order to perform the one or more computing tasks at a collective operation power;
a site server that is connected to the set of computing devices;
a frequency reader that is connected to the site server, the frequency reader being configured to read from the electricity grid the operation frequency of the electricity grid during an adjustment interval;
   wherein the site server is configured to
obtain from the frequency reader the operation frequency of the electricity grid during the adjustment interval;
determine a frequency difference between the operation frequency and a reference operation frequency; and
instruct the set of computing devices to change the collective operation power of the set of computing devices based on the frequency difference to adjust the operation frequency of the electricity grid.

Each of set of the computing devices may include a set of chips operating at a chipset power, and the site server may be further configured to instruct at least one of the set of computing devices to operate at a different chipset power in order to change the collective operation power of the set of computing devices.

The site server may be further configured to change the collective operation power of the set of computing devices by a load change limit at most.

The reference operation frequency may be a minimum operation frequency allowed in the electricity grid, and the site server may be further configured to
determine the frequency difference as a percentage difference that the operation frequency of the electricity grid during the adjustment interval is below the minimum operation frequency;
determine a below proportion of the percentage difference to a maximal below percentage; and
determine the below proportion times the load change limit to be a power reduction value.

The site server may be further configured to instruct each of the set of computing devices to reduce the chipset power of each of the set of computing devices in order to reduce the collective operation power of the set of computing devices by the power reduction value.

The site server may be further configured to
determine a chipset reduction proportion of the power reduction value to a collective chipset power of the set of computing devices; and
instruct each of the set of computing devices to reduce the chipset power of each of the set of computing devices by the chipset reduction proportion.

The site server may be further configured to instruct a subset of the set of computing devices to reduce the chipset power of each of those computing devices in order to reduce a collective chipset power of the subset of computing devices by the power reduction value.

The reference operation frequency may be a maximum operation frequency allowed in the electricity grid, and the site server may be further configured to
determine the frequency difference as a percentage difference that the operation frequency of the electricity grid during the adjustment interval is above the maximum operation frequency;
determine a above proportion of the percentage difference to a maximal above percentage; and
determine the above proportion times the load change limit to be a power increase value.

The site server may be further configured to instruct each of the set of computing devices to increase the chipset power of each of the set of computing devices in order to increase the collective operation power of the set of computing devices by the power increase value.

The site server may be further configured to
determine a chipset increase proportion of the power increase value to a collective chipset power of the set of computing devices; and
instruct each of the set of computing devices to increase the chipset power of each of the se of computing devices by the chipset increase proportion.

The site server may be further configured to instruct a subset of the set of computing devices to increase the chipset power of each of those computing devices in order to increase a collective chipset power of the subset of computing devices by the power increase value.

The site server may be further configured to
determine a first financial return assuming the site server keeps changing the collective operation power of the set of computing devices for a period of time;
determine a second financial return assuming the set of computing devices keep performing the one or more computing tasks without changing the collective operation power of the set of computing devices for the period of time; and
instruct the set of computing devices to change the collective operation power of the set of computing devices during the period of time only if the first financial return is greater than the second financial return.

The one or more computing tasks may comprise proof of work.

The period of time may include one of the following periods of time:
a 6-second period of time;
a 60-second period of time; and
a 5-minute period of time.

There is provided a computer-implemented method for adjusting an operation frequency of an electricity grid, the electricity grid electrically connecting to a set of computing devices to power the set of computing devices, the set of computing devices are interconnected to perform one or more computing tasks at a collective operation power. The method may comprise, at a site server:
obtaining from a frequency reader connected to the electricity grid the operation frequency of the electricity grid during an adjustment interval;
determining, a frequency difference between the operation frequency during the adjustment interval and a reference operation frequency; and
instructing the set of computing devices to change the collective operation power of the set of computing devices based on the frequency difference to adjust the operation frequency of the electricity grid.

Each of set of the computing devices may include a set of chips operating at a chipset power. The computer-implemented method may further comprise, at the site server:
instructing at least one of the set of the computing devices to operate at a different chipset power in order to change the collective operation power of the set of the computing devices.

The computer-implemented method may further comprise, at the site server: changing the collective operation power of the set of computing devices by a load change limit at most.

The reference operation frequency may be a minimum operation frequency allowed in the electricity grid. The computer-implemented method may further comprise, at the site server:
determining the frequency difference as a percentage difference that the operation frequency of the electricity grid during the adjustment interval is below the minimum operation frequency;
determining a below proportion of the percentage difference to a maximal below percentage; and
determining the below proportion times the load change limit to be a power reduction value.

The computer-implemented method may further comprise, at the site server:
instructing each of the set of computing devices to reduce the chipset power of each of the set of computing devices in order to reduce the collective operation power of the set of computing devices by the power reduction value.

The computer-implemented method may further comprise, at the site server:
determining a chipset reduction proportion of the power reduction value to the collective chipset power of the set of computing devices; and
instructing each of the set of computing devices to reduce the chipset power of each of the set of computing devices by the chipset reduction proportion.

The computer-implemented method may further comprise, at the site server:
instructing a subset of the set of computing devices to reduce the chipset power of each of those computing devices in order to reduce a collective chipset power of the subset of computing devices by the power reduction value.

The reference operation frequency may be a maximum operation frequency allowed in the electricity grid. The computer-implemented method may further comprise, at the site server:
determining the frequency difference as a percentage difference that the operation frequency of the electricity grid during the adjustment interval is above the maximum operation frequency;
determining a above proportion of the percentage difference to a maximal above percentage; and
determining the above proportion times the load change limit to be a power increase value.

The computer-implemented method may further comprise, at the site server:
instructing each of the set of computing devices to increase the chipset power of each of the set of computing devices in order to increase the collective operation power of the set of computing devices by the power increase value.

The computer-implemented method may further comprise, at the site server:
determining a chipset increase proportion of the power increase value to a collective chipset power of the set of computing devices; and
instructing each of the set of computing devices to increase the chipset power of each of the se of computing devices by the chipset increase proportion.

The computer-implemented method may further comprise, at the site server:
instructing a subset of the set of computing devices to increase the chipset power of each of those computing devices in order to increase a collective chipset power of the subset of computing devices by the power increase value.

The computer-implemented method may further comprise, at the site server:
determining a first financial return assuming the site server keeps changing the collective operation power of the set of computing devices for a period of time;
determining a second financial return assuming the set of computing devices keep performing the one or more computing tasks without changing the collective operation power of the set of computing devices for the period of time; and
instructing the set of computing devices to change the collective operation power of the set of computing devices during the period of time only if the first financial return is greater than the second financial return.

The one or more computing tasks may comprise proof of work.

The period of time may include one of the following periods of time:
a 6-second period of time;
a 60-second period of time; and
a 5-minute period of time.

There is provided a site server for adjusting an operation frequency of an electricity grid in real time. The site server may comprise:
a processor;
a bus connected to the processor;
a computer-readable memory connected to the bus, the computer-readable memory being configured to store a set of computer-readable instructions;
a first communication interface connected to the bus, the first communication interface being configured to connect to a set of computing devices; and
a second communication interface connected to the bus, the second communication interface being configured to connect to a frequency reader;
wherein the processor is configured to read the set of the computer-readable instructions from the computer-readable memory and perform any one of the methods as described above.

There is provided a non-transitory computer-readable medium storing a set of instructions that when executed cause a site server to perform any one of the methods as described above.

Other aspects of the invention are also disclosed in the present disclosure.

### BRIEF DESCRIPTION OF THE DRAWINGS

Notwithstanding any other forms which may fall within the scope of the present disclosure, embodiments of the invention will now be described, by way of example only, with reference to the accompanying drawings in which:

FIG. 1 illustrates an electricity system in which an exemplary embodiment of the present disclosure is deployed;

FIG. 2 illustrates an electric load network in accordance with an exemplary embodiment of the present disclosure;

FIG. 3 illustrates a method performed by a site server in accordance with an exemplary embodiment of the present disclosure;

FIG. 4 is a graph illustrating the fluctuation of the operation power of the set of computing devices in response to the fluctuation of the operation frequency of the electricity grid in accordance with an embodiment of the present disclosure;

FIG. 5 is a graph illustrating the fluctuation of the operation power of the set of computing devices in response to the fluctuation of the operation frequency of the electricity grid in accordance with another embodiment of the present disclosure; and

FIG. 6 illustrates an exemplary structure of the site server in accordance with an exemplary embodiment of the present disclosure.

It should be noted in the accompanying drawings and description below that like or the same reference numerals in different drawings denote the same or similar elements.

### DESCRIPTION OF EMBODIMENTS

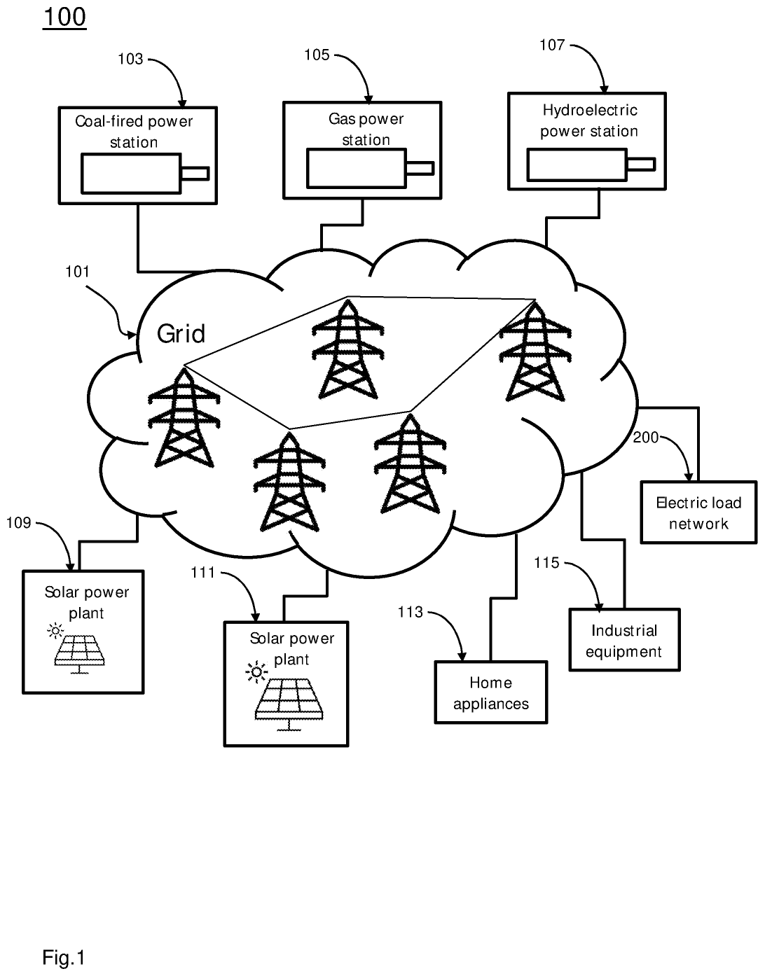

FIG. 1 illustrates an electricity system 100 in which an exemplary embodiment of the present disclosure is deployed.

As shown in FIG. 1, the supply side of the electricity system 100 includes rotor-based power stations, for example, a coal-fired power station 103, a gas power station 105, and a hydroelectric power station 107. The supply side of the electricity system 100 also includes invertor-based power stations, for example, solar power plants 109, 111. The supply side of the electricity system 100 can also include other forms of power stations that are able to generate electricity energy without departing from the scope of the present disclosure.

The electricity system 100 further includes an electricity transmission and distribution network 101 (i.e., the electricity grid or the “grid”) electrically connected to the power stations in the supply side. The supply side of the electricity system 100 generates electricity energy and supplies the electricity energy into the electricity grid 101. The electricity grid 101 transmits and distributes the electricity energy generated from the supply side to the load side of the electricity system 100.

As shown in FIG. 1, The load side of the electricity system 100 includes different types of loads that are electrically connected to the electricity grid 101 to consume the electricity energy transmitted and distributed from the electricity grid 101. The loads can be home appliances 113 for domestic use. The loads can be industrial equipment 115 for industrial use, for example, a smelting furnace in an aluminium smelting plant. An electric load network 200 in accordance with an exemplary embodiment of the present disclose is deployed in the electricity system 100 to function as a load of the electricity grid 101. The load side of the electricity system 100 can also include other forms of loads without departing from the scope of the present disclosure.

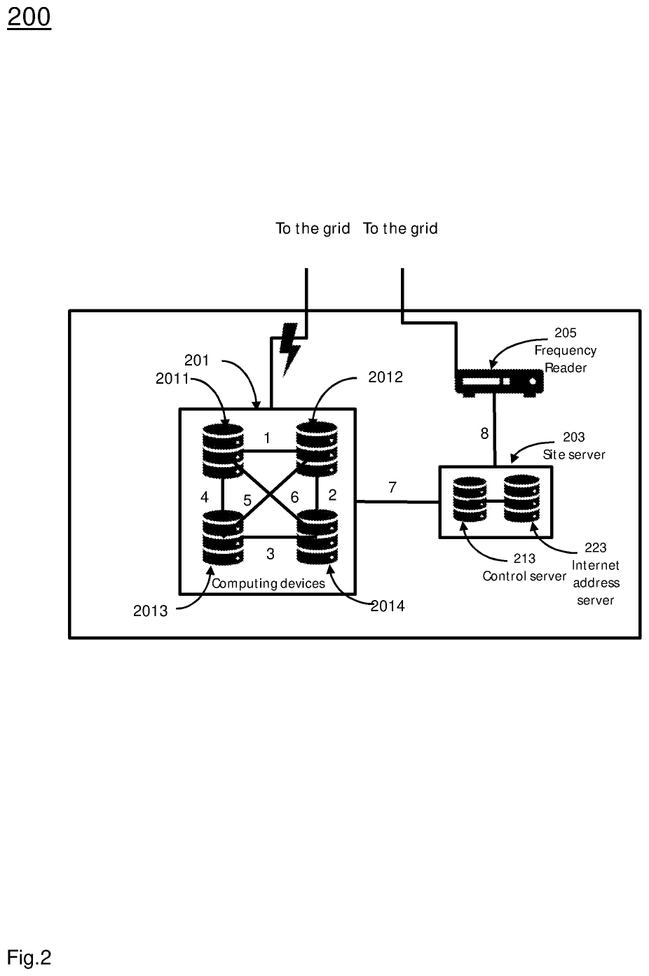

FIG. 2 illustrates the electric load network 200 for adjusting the operation frequency of the electricity grid 101 in real time in accordance with an exemplary embodiment of the present disclosure.

As shown in FIG. 2, the electric load network 200 includes a set of computing devices 201. The set of computing devices 201 include computing devices 2011, 2012, 2013 and 2014 that are interconnected to perform one or more computing tasks. Although there are four computing devices 2011, 2012, 2013 and 2014 in FIG. 2, the set of computing devices 201 may include more or less computing devices. The set of computing devices 201 can be interconnected through communication links 1 to 6 between them. The communication links 1 to 6 can be physical links or logical links or a combination of physical links and logical links. The communication links 1 to 6 operate under a network communication protocol to communicatively connect the set of computing devices 201. The communication protocol includes cellular network communication protocols (for example, 3G/4G/5G communication protocols), Internet/Ethernet communication protocols (for example, TCP/IP protocol stack), Wireless Local Area Network (for example, IEEE 802.11 technical standards), or a combination of the aforementioned protocols or technical standards. The communication protocol can be other communication protocols without departing from the scope of the present disclosure.

The set of computing devices 201 are configured to electrically connect to the electricity grid 101 to be powered by the electricity grid 101 in order to perform the one or more computing tasks. Each of the set of the computing devices 201 operates at an individual operation power. The sum of the individual operation powers of the computing devices 2011, 2012, 2013 and 2014 in the set of computing device 201 is referred to as a collective operation power. Therefore, in other words, the set of computing devices 201 perform the one or more computing tasks at the collective operation power. The set of computing devices 201 can be for example high-performance computers in a data centre or a cloud computing network.

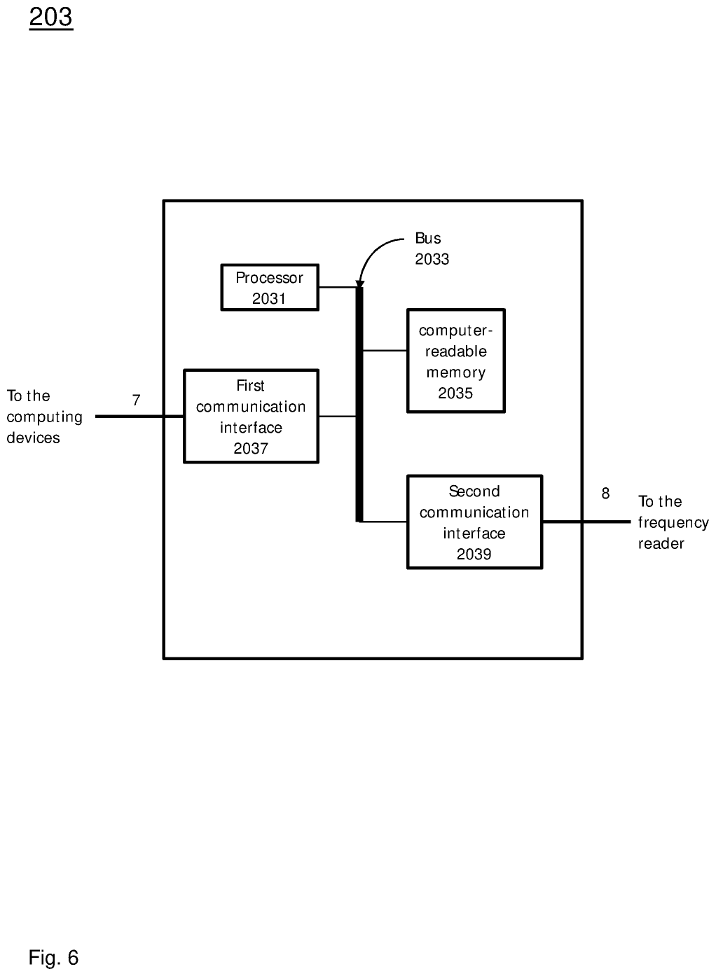

The electric load network 200 further includes a site server 203 that is communicatively connected to the set of computing devices 201 through a communication link 7 between the site server 203 and the set of computing devices 201. The communication link 7 can be a physical link or a logical link or a combination of a physical link and a logical link. The communication link 7 operates under a network communication protocol to communicatively connect the site server 203 to the set of computing devices 201. The communication protocol includes cellular network communication protocols (for example, 3G/4G/5G communication protocols), Internet/Ethernet communication protocols (for example, TCP/IP protocol stack including Transmission Control Protocol (TCP) and/or User Datagram Protocol (UDP)), Wireless Local Area Network (for example, IEEE 802.11 technical standards), or a combination of the aforementioned protocols or technical standards. The communication protocol can be other communication protocols without departing from the scope of the present disclosure. The site server 203 can be a standalone server. The site server 203 can also be a server stack including multiple physical or logical servers communicatively connected to each other without departing from the scope of the present disclosure. As an example, the site server 203 in FIG. 2 is a server stack including a control server 213 and an Internet address server 223. As another example, the site server 203 is a standalone server with the functionalities of the both the control server 213 and the Internet address server 223. An exemplary structure of the site server 203 as a standalone server is described with reference to FIG. 6.

The electric load network 200 further includes a frequency reader 205 that is communicatively connected to the site server 203 through a communication link 8. The communication link 8 can be a physical link or a logical link or a combination of a physical link and a logical link. The communication link 8 operates under a network communication protocol to communicatively connect the site server 202 to the set of computing devices 201. The network communication protocol includes cellular network communication protocols (for example, 3G/4G/5G communication protocols), Internet/Ethernet communication protocols (for example, TCP/IP protocol stack), Wireless Local Area Network (for example, IEEE 802.11 technical standards), or a combination of the aforementioned protocols or technical standards. The communication link 8 can also operate under a data communication protocol designed to communicatively connect industrial or computing devices. The data communication protocol includes Modbus protocol, RS232 serial data communication protocol, DB25 parallel data communication protocol, USB protocol, etc. The network or data communication protocol can also be other network or data communication protocols without departing from the scope of the present disclosure.

The frequency reader 205 is configured to read from the electricity grid 101 the operation frequency of the electricity grid during an adjustment interval. The adjustment interval is for example, 50 milliseconds. An example of the frequency reader 205 is an SEL Axion 2240 device being sold by Schweitzer Engineering Laboratories, Inc. During the adjustment interval, the site server 203 is configured to perform a method 300 for adjusting the operation frequency of the electricity grid 101 in real time. The site server 203 is also configured to perform other method steps described in the present disclosure. If the site server 203 is a standalone server, these method steps are performed at the site server 203. If the site server 203 is a server stack including, for example, the control server 213 and the Internet address server 223, as shown in FIG. 2, the performing of these method steps can be distributed to the control server 213 and the Internet address server 223 without departing from the scope of the present disclosure. Further, for easy description, one or more particular steps may be described in the present disclosure as being performed at one of the control server 213 and the Internet address server 223, such description however does not exclude the scenario where the particular one or more steps are performed at the other one of the control server 213 and the Internet address server 223.

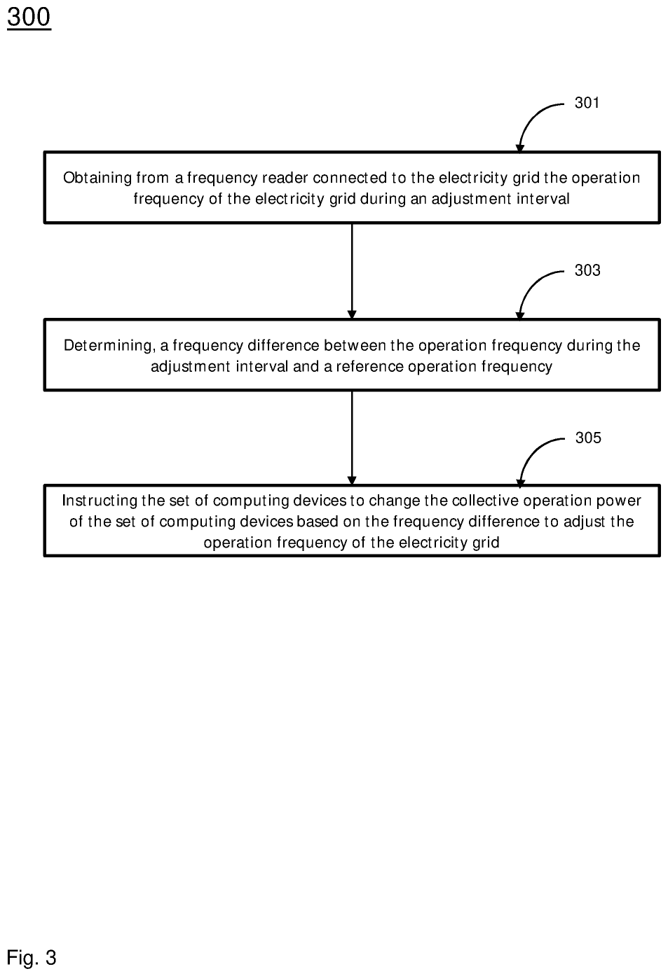

FIG. 3 illustrates the method 300 performed by the site server 203 in accordance with an exemplary embodiment of the present disclosure.

As shown in FIG. 3, at step 301, the site server 203 obtains from the frequency reader 205 the operation frequency of the electricity grid 101 during the adjustment interval. Specifically, the operation frequency read by the frequency reader 205 is sent from the frequency reader 205 to the site server 203 via the communication link 8.

At step 303, the site server 203 determines a frequency difference between the operation frequency and a reference operation frequency. The reference operation frequency can be the primary operation frequency of the electricity grid 101, for example, 50 Hz in Australia. The reference operation frequency can also be a lower limit of the safe frequency band, or the minimum safe operation frequency of the electricity grid 101, which is 49.85 Hz in Australia. The reference operation frequency can also be an upper limit of the safe frequency band, or the maximum safe operation frequency of the electricity grid 101, which is 50.15 Hz in Australia. In reality, the operation frequency of the electricity grid 101 almost always fluctuate over time and does not stay at a particular frequency. Therefore, there is almost always a frequency difference between the reference operation frequency and the operation frequency during a particular adjustment interval.

At step 305, the site server 203 instructs the set of computing devices 201 to change the collective operation power of the set of computing devices 201 based on the frequency difference to adjust the operation frequency of the electricity grid. For example, when the frequency difference indicates the operation frequency is below the reference operation frequency, which means the operation frequency needs to be raised for safety purposes, the site server 203 sends a first command to the set of the computing devices 201 instructing the set of computing devices 201 to lower the collective operation power of the set of computing devices 201 while performing the one or more computing tasks. This way, the operation frequency of the electricity grid 101 will be raised in response to the lowering of the collective operation power of the set of computing devices 201.

On the other hand, when the frequency difference indicates the operation frequency is above the reference operation frequency, which means the operation frequency needs to be lowered for safety purposes, the site server 203 sends a second command to the set of computing devices 201 instructing the set of computing devices 201 to raise the collective operation power of the set of computing devices 201 while performing the one or more computing tasks. This way, the operation frequency of the electricity grid 101 will be lowered in response to the raising of the collective operation power of the set of computing devices 201.

As described above, the set of computing devices 201 in the present disclosure are used as a load of the electricity grid 101 to adjust the operation frequency of the electricity grid 100. Particularly, power consumption by the set of computing devices 201 is controlled on a per computing device level to adjust the operation frequency of the electricity grid 100. This is particularly advantageous when the electricity system 100 is evolving towards green energy. With the evolution towards green energy, there will be less and less rotor-based power stations (for example, the coal-fired power station 103, the gas power station 105, and the hydroelectric power station 107), which are traditionally used to adjust the operation frequency of the electricity grid 101 by adjusting operation of the rotors in the generators, while there will be more and more invertor-based power stations (for example, solar power plants 109, 111) deployed. The invertor-based power stations do not rely on the rotation of rotors to generate the electricity energy simply because they do not have the rotors (solar power plants generate electricity energy by using solar panels). The above method 300 does not adjust the rotation of any rotors but adjusts the collective operation power of the set of computing devices 201 as a load of the electricity grid 101 while performing their computing task(s).

In one embodiment, each of the individual computing devices 2011, 2012, 2013 and 2014 in the set of computing devices 201 includes a set of chips designed to performing the one or more computing tasks. For example, the set of chips can be integrated circuits for central processing units (CPU) or graphics processing units (GPU). The set of chips of the individual computing devices 2011, 2012, 2013 and 2014 is powered by the electricity grid 101 at a chipset power to perform the one or more computing tasks. The electricity energy consumed by the set of chips normally accounts for a substantial portion of the electricity energy consumed by the individual computing device 2011, 2012, 2013 and 2014. Other parts (for example, the cooling fan) of the computing device 2011, 2012, 2013 and 2014 may consume some electricity energy as well. Therefore, it makes sense to change the individual operation power of the individual computing device 2011, 2012, 2013 and 2014 by changing the chipset power of the set of chips of the individual computing device 2011, 2012, 2013 and 2014. The sum of the chipset powers of the computing devices 2011, 2012, 2013 and 2014 in the set of computing devices 201 is referred to as a collective chipset power. The collective chipset power of the set of computing devices 201 is generally less than the collective operation power of the set of computing devices 201. However, if the set of chips is the only thing that consume electricity energy in each of the set of computing devices 201, the collective chipset power is substantially equal to the collective operation power of the set of computing devices 201. For example, if the computing devices 2011, 2012, 2013 and 2014 only have respective set of chips to provide computing capabilities and a separate cooling system is deployed to cool down the computing devices 2011, 2012, 2013 and 2014, then the collective chipset power is substantially equal to the collective operation power of the set of computing devices 201.

The site server 203 is further configured to instruct at least one of the computing devices 2011, 2012, 2013 and 2014 to operate at a different chipset power in order to change the collective operation power of the set of computing devices 201. Particularly, the site server 203 can send an instruction to the at least one of the computing devices 2011, 2012, 2013 and 2014 to change frequency-voltage settings of the sets of chips of the at least one computing devices. The changes to the frequency-voltages of the set of chips cause those computing devices to operate at a different chipset power.

The electric load network 200 in the present disclosure, which can adjust or control the operation frequency of the electricity grid 101, may provide a load (i.e., the collective operation power) of the order of megawatts (MWs) or gigawatts (GWs) if the set of computing devices 201 include thousands or tens of thousands of computing devices or more, but only a fraction of the full load is enabled by the energy market regulator (for example, Australian Energy Market Operator or AEMO in Australia) to adjust the operation frequency of the electricity grid 101. This means the site server 203 is configured to change the collective operation power of the set of computing devices 201 by the enabled load at most. The enabled load is also referred to as a load change limit in the present disclosure. The load change limit is less than or equal to the full load provided by the electric load network 200.

In one embodiment, the electric load network 200 is used to raise the operation frequency of the electricity grid 101. In this embodiment, the reference operation frequency is the minimum safe operation frequency, for example, 49.85 Hz in Australia. The site server 203 is configured to determine the frequency difference as a percentage difference that the operation frequency of the electricity grid 101 during the adjustment interval is below the minimum operation frequency. The site server 203 also determines a proportion of the percentage difference to a maximal below percentage, referred to as a below proportion hereinafter. The site server 230 then determines the below proportion times the load change limit (i.e., the enabled load) to be a power reduction value. Two examples 1 and 2 are given below to explain how to determine the power reduction value.

### Example 1

If the operation frequency of the electricity grid 101 during the adjustment interval is 49.35 Hz, then the percentage difference that the operation frequency of the electricity grid 101 is below the minimum operation frequency 49.85 Hz is (49.85−49.35)/49.85=1%. If the maximal below percentage is 2%, as set by the energy market regulator (for example, Australian Energy Market Operator or AEMO in Australia), then the below proportion is (1%)/(2%)=50%. As a result, the power reduction value is 50%×load change limit (i.e., the enabled load). This means the collective operation power of the set of computing devices 201 needs to be reduced by 50%×load change limit (i.e., the enabled load). Therefore, if the load change limit (or enabled load) of the set of computing devices 201 is 3 MW, as enabled by the energy market regulator, then the collective operation power of the set of computing device 201 needs to be reduced by 1.5 MW (i.e., 50%×3 MW) in order to raise the operation frequency of the electricity grid 101.

### Example 2

If the operation frequency of the electricity grid 101 during the adjustment interval is 48.85 Hz, then the percentage difference that the operation frequency of the electricity grid 101 is below the minimum operation frequency 49.85 Hz is (49.85-48.85)/49.85=2% and the below proportion is (2%)/(2%)=100%. As a result, the power reduction value is 100%×load change limit. This means the collective operation power of the set of computing devices 201 needs to be reduced by 100%×load change limit, or the enabled load needs to be completely removed from the set of computing devices 201. Therefore, the collective operation power of the set of computing device 201 needs to be reduced by 3 MW (i.e., 100%×3 MW) in order to raise the operation frequency of the electricity grid 101.

As described above, the collective operation power of the set of computing device 201 can be changed by changing the collective chipset power of the set of computing devices 201. Particularly, reducing the collective operation power of the set of computing devices 201 by the power reduction value can be achieved by reducing the collective chipset power of the set of computing devices 201 by the power reduction value. There are different ways of reducing the collective chipset power of the set of computing devices 201, two examples 3 and 4 are given below without excluding other embodiments.

### Example 3

The site server 203, for example, the control server 213 of the site server, maintains a machine register 1 including machine IDs to identify all the computing devices in the set of computing devices 201, their IP addresses, the individual reserved powers of the set of computing devices 201 and cumulative reserved powers. For ease of description, the machine IDs in the machine register 1 are consecutively numbered, 1, 2, 3, 4 . . . , 758, 759, 760, . . . . The individual reserved powers indicate the amounts of the chipset power that can be reduced or increased from the individual computing devices. The cumulative reserved power for computing device N is the sum of the individual reserved powers of computing devices 1 to N. For example, the cumulative reserved power for computing device 3 is the sum of the individual reserved powers of computing devices 1 to 3, which is 5.5 KW, as shown in the machine register 1. The IP addresses can be assigned by for example the Internet address server 223 according to the Dynamic Host Configuration Protocol (DHCP) that operates on the Internet address server 223. DHCP ensures that IP addresses and their associated leases remain consistent for each computing device. This allows the control server 213 to send TCP or UDP socket instructions to the correct computing devices 201, and in turn enables the control server 213 to change the power consumption settings of the computing devices 201 on a per computing device level.

Machine Register 1

| Machine | | Reserved | Cumulative Reserved |
|---|---|---|---|
| ID | IP Address | Power (KW) | Power (KW) |
| 1 | 192.168.0.1 | 1.4 | 1.4 |
| 2 | 192.168.0.2 | 0.8 | 2.2 |
| 3 | 192.168.0.3 | 3.3 | 5.5 |
| 4 | 192.168.0.4 | 2.8 | 8.3 |
| . . . | . . . | . . . | |
| 758 | 192.168.10.13 | 3.6 | 1500 |
| 759 | 192.168.10.14 | 1.6 | 1501.6 |
| 760 | 192.168.10.15 | 1.5 | 1503.1 |
| . . . | . . . | . . . | . . . |

The site server 203 or the control server 213 of the site server 213 can be configured to instruct each of the set of computing devices 201 to reduce the chipset power of each of the set of computing devices 201 in order to reduce the collective operation power of the set of computing devices 201 by the power reduction value. Specifically, the site server 203 determines a proportion of the power reduction value to the collective chipset power of the set of computing devices 201, referred to as a chipset reduction proportion hereinafter. The site server 203 further instructs each of the set of computing devices 201 to reduce the chipset power of each of the set of computing devices 201 by the chipset reduction proportion. For example, the control server 213 of the site server 203 sends an instruction via TCP or UDP sockets to each of the set of computing devices 201 identified by their respective IP addresses. In response to receipt of the instruction, each of the set of computing devices 201 reduces its chipset power by the chipset reduction proportion according to, for example, their respective internal Application Programming Interface (API). This way, the collective operation power of the set of computing devices 201 can be reduced by the power reduction value.

In the above Example 1, the power reduction value is 1.5 MW. If the set of computing devices 201 are operating at a collective chipset power of 35 MW during the adjustment interval, then chipset reduction proportion is 1.5 MW/35 MW=4.3%. This means the site server 203 instructs each of the set of computing devices 201 to reduce the chipset power of each of the set of computing devices by 4.3% by changing their frequency-voltage settings. As a result, the collective operation power of the set of computing devices 201 is reduced by 1.5 MW.

In the above Example 2, the power reduction value is 3 MW, then chipset reduction proportion is 3 MW/35 MW=8.6%. This means the site server 203 instructs each of the set of computing devices 201 to reduce the chipset power of each of the set of computing devices by 8.6% by changing their frequency-voltage settings. As a result, the collective operation power of the set of computing devices 201 is reduced by 3 MW.

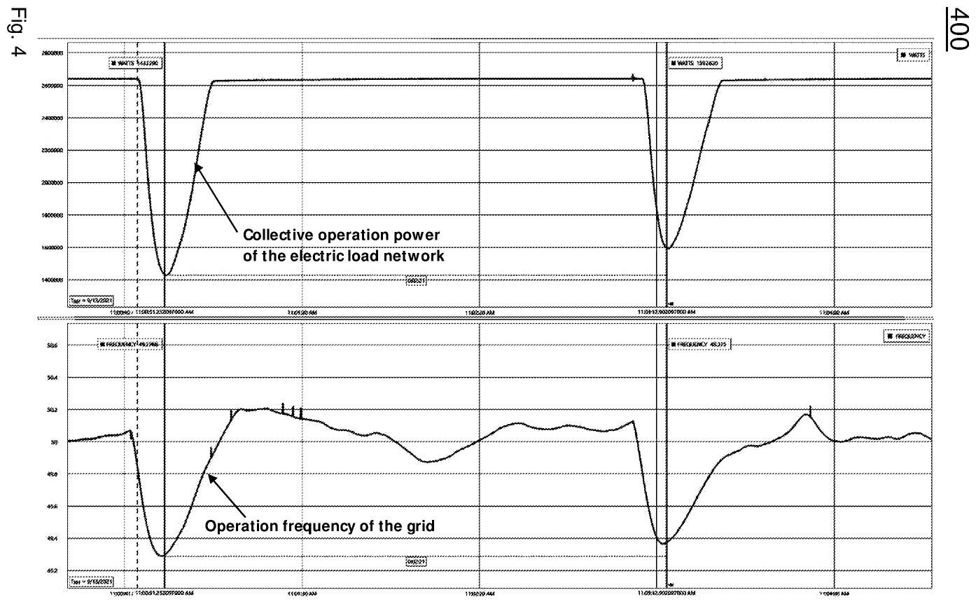

FIG. 4 is a graph 400 illustrating the fluctuation of the operation power of the set of computing devices 201 in response to the fluctuation of the operation frequency of the electricity grid 101 in accordance with Example 3.

### Example 4

In the above Example 3, the site server 203 instructs each of the set of computing device 201 to reduce their chipset powers. The process described in Example 3 will become less responsive if the set of computing device 201 include many computing devices, say as many as 25,000 or even more computing devices, because it takes more time to send the instruction to 25,000 or more computing devices and for the 25,000 or more computing devices to change their voltage-frequency settings. In Example 4, the site server 203 is configured to instruct some (not all) of the computing devices 2011, 2012, 2013 and 2014, i.e., a subset of the set of computing devices 201, to reduce the chipset power of each of those computing devices in order to reduce the collective operation power of the set of computing devices by the power reduction value.

An exemplary method of determining the subset of the set of computing device 201 in Example 4 is provided below.

In the above Example 1, the power reduction value is 1.5 MW. This means that the collective chipset power of the set of the computing devices 201 needs to be reduced by 1.5 MW. The site server 203 or the control sever 213 of the site server 203 searches the machine register 1 for a cumulative reserved power of 1.5 MW (i.e., 1500 KW). The Machine ID that correspond to 1.5 MW is 758. Therefore, the site server 203 determines that computing devices 1 to 758 are the subset of the set of computing devices 201. As a result, the site server 203 sends an instruction to the computing devices 1 to 758 to reduce their chipset powers by the corresponding individual reserved powers, respectively. For example, the control server 213 of the site server 203 sends an instruction via TCP or UDP sockets to each of the subset of the set of computing devices 201 identified by their respective IP addresses, from 192.168.0.1 (Machine ID: 1) to 192.168.10.13 (Machine ID: 758). In response to receipt of the instruction, each of the subset of the set of computing devices 201 reduces its chipset power by its corresponding individual reserved power according to, for example, their respective internal Application Programming Interface (API). This way, the collective chipset power of the set of computing devices 201 is reduced by the power reduction value of 1.5 MW, and thus the collective operation power of the set of computing devices 201 is reduced by the power reduction value of 1.5 MW.

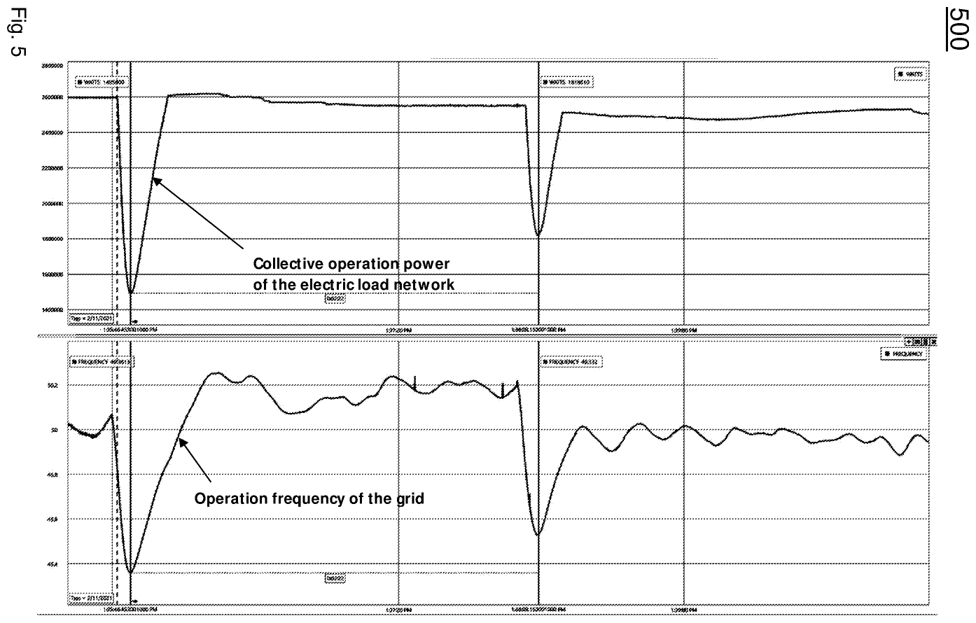

FIG. 5 is a graph 500 illustrating the fluctuation of the operation power of the set of computing devices 201 in response to the fluctuation of the operation frequency of the electricity grid 101 in accordance with Example 4.

In one embodiment, the electric load network 200 is used to lower the operation frequency of the electricity grid 101. In this embodiment, the reference operation frequency is the maximum safe operation frequency, for example, 50.15 Hz in Australia. The site server 203 is configured to determine the frequency difference as a percentage difference that the operation frequency of the electricity grid 101 during the adjustment interval is above the maximum operation frequency. The site server 203 also determines a proportion of the percentage difference to a maximal above percentage, referred to as an above proportion hereinafter. The site server 230 then determines the above proportion times the load change limit (i.e., the enabled load) to be a power increase value. Two examples 5 and 6 are given below to explain how to determine the power increase value.

### Example 5

If the operation frequency of the electricity grid 101 during the adjustment interval is 50.65 Hz, then the percentage difference that the operation frequency of the electricity grid 101 is above the maximum operation frequency 50.15 Hz is (50.65−50.15)/50.15=1%. If the maximal above percentage is 2%, as set by the energy market regulator (for example, Australian Energy Market Operator or AEMO in Australia), then the above proportion is (1%)/(2%)=50%. As a result, the power increase value is 50%×load change limit (i.e., the enabled load). This means the collective operation power of the set of computing devices 201 needs to be increased by 50%×load change limit (i.e., the enabled load). Therefore, if the load change limit (or enabled load) of the set of computing devices 201 is 3 MW, as enabled by the energy market regulator, then the collective operation power of the set of computing device 201 needs to be increased by 1.5 MW (i.e., 50%×3 MW) in order to lower the operation frequency of the electricity grid 101.

### Example 6

If the operation frequency of the electricity grid 101 during the adjustment interval is 51.15 Hz, then the percentage difference that the operation frequency of the electricity grid 101 is above the maximum operation frequency 50.15 Hz is (51.15−50.15)/50.15=2% and the above proportion is (2%)/(2%)=100%. As a result, the power increase value is 100%×load change limit. This means the collective operation power of the set of computing devices 201 needs to be increased by 100%×load change limit, or the enabled load needs to be fully added to the set of computing devices 201. Therefore, the collective operation power of the set of computing device 201 needs to be increased by 3 MW (i.e., 100%×3 MW) in order to lower the operation frequency of the electricity grid 101.

As described above, the collective operation power of the set of computing device 201 can be changed by changing the collective chipset power of the set of computing devices 201. Particularly, increasing the collective operation power of the set of computing devices 201 by the power increase value can be achieved by increasing the collective chipset power of the set of computing devices 201 by the power increase value. There are different ways of increasing the collective chipset power of the set of computing devices 201, two examples 7 and 8 are given below without excluding other embodiments.

### Example 7

The site server 203 can be configured to instruct each of the set of computing devices 201 to increase the chipset power of each of the set of computing devices 201 in order to increase the collective operation power of the set of computing devices 201 by the power increase value. Specifically, the site server 203 determines a proportion of the power increase value to the collective chipset power of the set of computing devices 201, referred to as a chipset increase proportion hereinafter. The site server 203 further instructs each of the set of computing devices 201 to increase the chipset power of each of the set of computing devices 201 by the chipset increase proportion. For example, the control server 213 of the site server 203 sends an instruction via TCP or UDP sockets to each of the set of computing devices 201 identified by their respective IP addresses. In response to receipt of the instruction, each of the set of computing devices 201 increases its chipset power by the chipset increase proportion according to, for example, their respective internal Application Programming Interface (API). This way, the collective operation power of the set of computing devices 201 can be increased by the power increase value.

In the above Example 5, the power increase value is 1.5 MW. If the set of computing devices 201 are operating at a collective chipset power of 35 MW during the adjustment interval, then chipset increase proportion is 1.5 MW/35 MW=4.3%. Then the site server 203 instructs each of the set of computing devices 201 to increase the chipset power of each of the set of computing devices 201 by 4.3% by changing their frequency-voltage settings. As a result, the collective operation power of the set of computing devices 201 is increased by 1.5 MW.

In the above Example 6, the power increase value is 3 MW, then chipset increase proportion is 3 MW/35 MW=8.6%. The site server 203 instructs each of the set of computing devices 201 to increase the chipset power of each of the set of computing devices 2001 by 8.6% by changing their frequency-voltage settings. As a result, the collective operation power of the set of computing devices 201 is increased by 3 MW.

### Example 8

In the above Example 7, the site server 203 instructs each of the set of computing device 201 to increase their chipset powers. The process described in Example 7 will become less responsive if the set of computing devices 201 include many computing devices, say as many as 25,000 or even more computing devices, because it takes more time to send the instruction to 25,000 or more computing devices and for the 25,000 or more computing devices to change their voltage-frequency settings. In Example 8, the site server 203 is configured to instruct some (not all) of the computing devices 2011, 2012, 2013 and 2014, i.e., a subset of the set of computing devices 201, to increase the chipset power of each of those computing devices in order to increase the collective operation power of the set of computing devices 201 by the power increase value.

An exemplary method of determining the subset of the set of computing devices 201 in Example 8 is provided below.

In the above Example 5, the power increase value is 1.5 MW. This means that the collective chipset power of the set of the computing devices 201 needs to be increased by 1.5 MW. The site server 203 or the control sever 213 of the site server 203 searches the machine register 1 for a cumulative reserved power of 1.5 MW (i.e., 1500 KW). The Machine ID that correspond to 1.5 MW is 758. Therefore, the site server 203 determines that computing devices 1 to 758 are the subset of the set of computing devices 201. As a result, the site server 203 sends an instruction to the computing devices 1 to 758 to increase their chipset powers by the corresponding individual reserved powers, respectively. For example, the control server 213 of the site server 203 sends an instruction via TCP or UDP sockets to each of the subset of the set of computing devices 201 identified by their respective IP addresses, from 192.168.0.1 (Machine ID: 1) to 192.168.10.13 (Machine ID: 758). In response to receipt of the instruction, each of the subset of the set of computing devices 201 increases its chipset power by its corresponding individual reserved power according to, for example, their respective internal Application Programming Interface (API). This way, the collective chipset power of the set of computing devices 201 is increased by the power increase value of 1.5 MW, and thus the collective operation power of the set of computing devices 201 is increased by the power increase value of 1.5 MW.

In one embodiment, the electrical load network 200 participates in a frequency control process regulated by the energy market regulator, for example, AEMO in Australia. The frequency control services (i.e., raise the operation frequency of the electricity grid 101 or lower the operation frequency of the electricity grid 101 when necessary) provided by the electric load network 200 may last for a period of time, for example, 6 seconds, 60 seconds, or 5 minutes with an adjustment interval of 50 milliseconds in Australia, if accepted by the energy market regulator. The period of time and the adjustment interval could be different in other countries without departing from the scope of the present disclosure. The energy market regulator pays a fee to the operator of the electric load network 200 for providing the frequency control services. However, if the collective operation power of the set of computing devices 201 is lowered to raise the operation frequency of the electricity grid 101, the performing of the one or more computing tasks may be negatively affected. This is particularly problematic if the set of computing devices 201 are performing a complex computing task for a financial return. As an example, the set of computing devices 201 can be used to perform proof of work tasks for cryptocurrency mining, e.g., bitcoin mining. The operator of the electric load network 200 will be rewarded with a certain amount of cryptocurrency for completing the proof of work tasks. As another example, the set of computing devices 201 can be used to provide high-performance computing services, e.g., biological data analysis, astronomical data analysis, and the operator of the electric load network 200 will be rewarded with a financial return for providing the high-performance computing services. Lowering the collective operation power of the set of computing devices 201 means lowering the computing speed of the set of computing devices 201, which leads to delays in completing the computing task and getting rewarded for completing the computing task. In this embodiment, the site server 203 is further configured to determine a first financial return assuming the site server 203 keeps changing the collective operation power of the set of computing devices 201 for the period of time and determines a second financial return assuming the set of computing devices 201 keep performing the one or more computing tasks without changing the collective operation power of the set of computing devices 201 for the period of time. Depending on the nature of the computing task(s), one or more factors can be taken into account in determining the first or second financial return, for example, cryptocurrency/fiat exchange rate (e.g., Bitcoin/Australian Dollar), Bitcoin network difficulty, network capacity, Coinbase reward, and transaction fees, power price, frequency control service fee, etc.

The site server 203 instructs the set of computing devices 201 to change the collective operation power of the set of computing devices 201 during the period of time only if the first financial return is greater than the second financial return. This means the electric load network 200 provides the frequency control services only when the fee paid by the energy market regulator is higher than the financial return from performing the computing task.

FIG. 6 illustrates an exemplary structure of the site server 203 in accordance with an exemplary embodiment of the present disclosure.

As shown in FIG. 6, the site server 203 comprises a processor 2031, a bus 2033, a computer-readable memory 2035, a first communication interface 2037, and a second communication interface 2039. The processor 2031 is connected to the computer-readable memory 2035, the first communication interface 2037, and the second communication interface 2039 via the bus 2033. Therefore, the processor 2031 is able receive instructions and/or data from these components and send the instructions and/or data to these components. The processor 2031 is one of, but not limited to, a general-purpose processor, an application specific integrated circuit (ASIC) and a field-programmable gate array (FPGA). The computer-readable memory 2035 is configured to store a set of computer-readable instructions. The computer-readable instructions can be written in a computer-programming language, for example, Python. The first communication interface 2037 is configured to connect to the set of computing devices 201 via the communication link 7 as shown in FIG. 2, while the second communication interface 2039 is configured to connect to the frequency reader 205 via the communication link 8 as shown in FIG. 2.

The processor 2031 is configured to read the computer-readable instructions from the computer-readable memory 2035 and execute the computer-readable instructions to perform the method steps as described above.

In accordance with another embodiment of the present invention, the computer-readable instructions are made available on a non-transitory computer-readable medium. The non-transitory computer-readable medium, may be, but not limited to Read-Only Memory (ROM), Random Access Memory (RAM), Electrically Erasable Programmable Read-Only Memory (EEPROM), CD-ROM, DVD-ROM, Flash Drive, a cloud storage unit, a File Transport Protocol (FTP) server, etc. The set of computer-readable instructions may be loaded in a form of a computer software program into the computer-readable memory 2035. When executed by the processor 2031 of the site server 203, the site server 203 performs the method steps as described above.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is meant to provide the broadest scope, consistent with the principles and the novel and inventive features disclosed or suggested herein. Accordingly, the disclosure is anticipated to hold on to all other such alternatives, modifications, and variations that fall within the scope of the present disclosure and appended claims.

In the claims which follow and in the preceding description of the invention, except where the context requires otherwise due to express language or necessary implication, the word “comprise” or variations such as “comprises” or “comprising” are used in an inclusive sense, i.e. to specify the presence of the stated features but not to preclude the presence or addition of further features in various embodiments of the invention.

Any one of the terms: including or which includes or that includes as used herein is also an open term that also means including at least the elements/features that follow the term, but not excluding others. Thus, including is synonymous with and means comprising.

1. An electric load network for adjusting an operation frequency of an electricity grid in real time, the electric load network comprising:
a set of computing devices interconnected to perform one or more computing tasks, the set of computing devices being configured to electrically connect to the electricity grid to be powered by the electricity grid in order to perform the one or more computing tasks at a collective operation power;
a site server that is connected to the set of computing devices;
a frequency reader that is connected to the site server, the frequency reader being configured to read from the electricity grid the operation frequency of the electricity grid during an adjustment interval;
wherein the site server is configured to
obtain from the frequency reader the operation frequency of the electricity grid during the adjustment interval;
determine a frequency difference between the operation frequency and a reference operation frequency; and
instruct the set of computing devices to change the collective operation power of the set of computing devices based on the frequency difference to adjust the operation frequency of the electricity grid.

2. The electric load network of claim 1, wherein each of set of the computing devices includes a set of chips operating at a chipset power, and the site server is further configured to instruct at least one of the set of computing devices to operate at a different chipset power in order to change the collective operation power of the set of computing devices.

3. The electric load network of claim 2, wherein the site server is further configured to change the collective operation power of the set of computing devices by a load change limit at most.

4. The electric load network of claim 3, wherein the reference operation frequency is a minimum operation frequency allowed in the electricity grid, and the site server is further configured to
determine the frequency difference as a percentage difference that the operation frequency of the electricity grid during the adjustment interval is below the minimum operation frequency;
determine a below proportion of the percentage difference to a maximal below percentage; and
determine the below proportion times the load change limit to be a power reduction value.

5. The electric load network of claim 4, wherein the site server is further configured to
instruct each of the set of computing devices to reduce the chipset power of each of the set of computing devices in order to reduce the collective operation power of the set of computing devices by the power reduction value.

6. The electric load network of claim 5, wherein the site server is further configured to
determine a chipset reduction proportion of the power reduction value to a collective chipset power of the set of computing devices; and
instruct each of the set of computing devices to reduce the chipset power of each of the set of computing devices by the chipset reduction proportion.

7. The electric load network of claim 4, wherein the site server is further configured to
instruct a subset of the set of computing devices to reduce the chipset power of each of those computing devices in order to reduce a collective chipset power of the set of computing devices by the power reduction value.

8. The electric load network of claim 3, wherein the reference operation frequency is a maximum operation frequency allowed in the electricity grid, and the site server is further configured to
determine the frequency difference as a percentage difference that the operation frequency of the electricity grid during the adjustment interval is above the maximum operation frequency;
determine a above proportion of the percentage difference to a maximal above percentage; and
determine the above proportion times the load change limit to be a power increase value.

9. The electric load network of claim 8, wherein the site server is further configured to
instruct each of the set of computing devices to increase the chipset power of each of the set of computing devices in order to increase the collective operation power of the set of computing devices by the power increase value.

10. The electric load network of claim 9, wherein the site server is further configured to
determine a chipset increase proportion of the power increase value to a collective chipset power of the set of computing devices; and
instruct each of the set of computing devices to increase the chipset power of each of the set of computing devices by the chipset increase proportion.

11. The electric load network of claim 8, wherein the site server is further configured to
instruct a subset of the set of computing devices to increase the chipset power of each of those computing devices in order to increase a collective chipset power of the set of computing devices by the power increase value.

12. The electric load network of any one of the preceding claims, wherein the site server is further configured to
determine a first financial return assuming the site server keeps changing the collective operation power of the set of computing devices for a period of time;
determine a second financial return assuming the set of computing devices keep performing the one or more computing tasks without changing the collective operation power of the set of computing devices for the period of time; and
instruct the set of computing devices to change the collective operation power of the set of computing devices during the period of time only if the first financial return is greater than the second financial return.

13. The electric load network of any one of the preceding claims, wherein the one or more computing tasks comprise proof of work.

14. The electric load network of claim 12 or 13, wherein the period of time includes one of the following periods of time:
a 6-second period of time;
a 60-second period of time; and
a 5-minute period of time.

15. A computer-implemented method for adjusting an operation frequency of an electricity grid, the electricity grid electrically connecting to a set of computing devices to power the set of computing devices, the set of computing devices are interconnected to perform one or more computing tasks at a collective operation power, the method comprising, at a site server:
obtaining from a frequency reader connected to the electricity grid the operation frequency of the electricity grid during an adjustment interval;
determining, a frequency difference between the operation frequency during the adjustment interval and a reference operation frequency; and
instructing the set of computing devices to change the collective operation power of the set of computing devices based on the frequency difference to adjust the operation frequency of the electricity grid.

16. The computer-implemented method of claim 15, wherein each of set of the computing devices includes a set of chips operating at a chipset power, the method further comprising, at the site server:
instructing at least one of the set of the computing devices to operate at a different chipset power in order to change the collective operation power of the set of the computing devices.

17. The computer-implemented method of claim 16, further comprising, at the site server: changing the collective operation power of the set of computing devices by a load change limit at most.

18. The computer-implemented method of claim 17, wherein the reference operation frequency is a minimum operation frequency allowed in the electricity grid, the method further comprising, at the site server:
determining the frequency difference as a percentage difference that the operation frequency of the electricity grid during the adjustment interval is below the minimum operation frequency;
determining a below proportion of the percentage difference to a maximal below percentage; and
determining the below proportion times the load change limit to be a power reduction value.

19. The computer-implemented method of claim 18, further comprising, at the site server:
instructing each of the set of computing devices to reduce the chipset power of each of the set of computing devices in order to reduce the collective operation power of the set of computing devices by the power reduction value.

20. The computer-implemented method of claim 19, further comprising, at the site server:
determining a chipset reduction proportion of the power reduction value to the collective chipset power of the set of computing devices; and
instructing each of the set of computing devices to reduce the chipset power of each of the set of computing devices by the chipset reduction proportion.

21. The computer-implemented method of claim 18, further comprising, at the site server:
instructing a subset of the set of computing devices to reduce the chipset power of each of those computing devices in order to reduce a collective chipset power of the set of computing devices by the power reduction value.

22. The computer-implemented method of claim 17, wherein the reference operation frequency is a maximum operation frequency allowed in the electricity grid, the method further comprising, at the site server:
determining the frequency difference as a percentage difference that the operation frequency of the electricity grid during the adjustment interval is above the maximum operation frequency;
determining a above proportion of the percentage difference to a maximal above percentage; and
determining the above proportion times the load change limit to be a power increase value.

23. The computer-implemented method of claim 22, further comprising, at the site server:
instructing each of the set of computing devices to increase the chipset power of each of the set of computing devices in order to increase the collective operation power of the set of computing devices by the power increase value.

24. The computer-implemented method of claim 23, further comprising, at the site server:
determining a chipset increase proportion of the power increase value to a collective chipset power of the set of computing devices; and
instructing each of the set of computing devices to increase the chipset power of each of the se of computing devices by the chipset increase proportion.

25. The computer-implemented method of claim 22, further comprising, at the site server:
instructing a subset of the set of computing devices to increase the chipset power of each of those computing devices in order to increase a collective chipset power of the set of computing devices by the power increase value.

26. The computer-implemented method of any one of claims 15 to 25, further comprising, at the site server:
determining a first financial return assuming the site server keeps changing the collective operation power of the set of computing devices for a period of time;
determining a second financial return assuming the set of computing devices keep performing the one or more computing tasks without changing the collective operation power of the set of computing devices for the period of time; and
instructing the set of computing devices to change the collective operation power of the set of computing devices during the period of time only if the first financial return is greater than the second financial return.

27. The computer-implemented method of any one of claims 15 to 26, wherein the one or more computing tasks comprise proof of work.

28. The computer-implemented method of claim 26 or 27, wherein the period of time includes one of the following periods of time:
a 6-second period of time;
a 60-second period of time; and
a 5-minute period of time.

29. A site server for adjusting an operation frequency of an electricity grid in real time, the site server comprising:
a processor;
a bus connected to the processor;
a computer-readable memory connected to the bus, the computer-readable memory being configured to store a set of computer-readable instructions;
a first communication interface connected to the bus, the first communication interface being configured to connect to a set of computing devices; and
a second communication interface connected to the bus, the second communication interface being configured to connect to a frequency reader;
wherein the processor is configured to read the set of the computer-readable instructions from the computer-readable memory and perform the method as defined in any one of claims 15 to 28.

30. A non-transitory computer-readable medium storing a set of instructions that when executed cause a site server to perform the method as defined in any one of claims 15 to 28.
